(19) United States
(12) Patent Application Publication
(10) Pub. No.: US 2008/0142810 A1
(43) Pub. Date: Jun. 19, 2008

(54) Self assembled controlled luminescent transparent conductive photonic crystals for light emitting devices

(75) Inventors: Gary S. Tompa, Belle Mead, NJ (US); Shangzhu Sun, Hillsborough, NJ (US); Catherine E. Rice, Scotch Plains, NJ (US); Nick M. Sbrockey, Gaithersburg, MD (US); Lloyd G. Provost, Glen Ridge, NJ (US)

Correspondence Address: William L. Botjer, P.O. Box 478, Center Moriches, NY, 11934, US

(73) Assignee: Structured Materials Inc.

(21) Appl. No.: 11/973,766

(22) Filed: Oct. 10, 2007

Related U.S. Application Data
(60) Provisional application No. 60/850,310, filed on Oct. 10, 2006.

(51) Int. Cl. H01L 33/00

(52) U.S. Cl. 257/76; 438/26; 257/E33.064; 257/E33.025

(57) ABSTRACT

A transparent conductive oxide contact layer to enhance the spectral output of a light emitting device and a methodology for its deposition. The transparent conductive oxide deposited on the light emitting device so as to have a columnar structure. The transparent conductive oxide contact layer may be preferably ZnO doped with a conductive element. Light emitting phosphors may also be deposited within the transparent conductive oxide contact layer.

### REFERENCE TO RELATED APPLICATIONS

This application claims priority from U.S. provisional application Ser. No. 60/850,310 filed Oct. 10, 2006 the disclosure of which is hereby incorporated by reference.

### BACKGROUND OF THE INVENTION

The present invention is directed to the formation of an improved transparent conductive oxide (TCO) suitable for use as a contact layer on light emitting semiconductor devices such as Light Emitting Diodes (LEDs).

Light Emitting Diodes (LEDs) are an important lighting product. It is important to maximize light output efficiency and spectrum using the most economical methods. Disclosed is a technology to enhance light output efficiency, control and augment spectral output and a process to produce the disclosed technology. Further, the technology disclosed is also applicable to enhancing other light emission materials, such as organic light emitting diodes as well as being useful to enhance light absorption properties of devices.

We have developed high-performance self-assembled luminescent transparent conductive photonic crystals in a thin film that are ideal electrical contacts for enhancing the brightness (and efficiency) of mono- and multi-chrome light emitting diodes such as gallium nitride (GaN) based semiconducting light emitting devices and the like. Further, in another manifestation the technology includes the incorporation of luminescent centers in single, compositionally varied, or multiple layer structures for the further control or creation of spectral emission at wavelengths or ranges of wavelengths in addition to those emitted by the semiconducting device. The invention is also conducive to large area devices as it enables greater current spreading while allowing the light out. Additionally, this same technology is applicable to the enhancement of light capture in photonic devices. Lastly, we disclose a preferred process for the formation of the disclosed thin film invention.

Recently, there has been significant technical and commercial interest in GaN based devices, due to the wide bandgap, high breakdown field and high thermal conductivity of GaN. These properties enable high-power, high-frequency, and high-temperature devices, as well as high-power optoelectronic devices for use in blue/UV wavelength range Light emitting diodes (LED's) operating at blue/UV wavelengths are a key component for future solid state lighting applications. The development of an efficient, high-volume production technology for high-brightness GaN LED's will enable these products to capture a significant share of the total lighting market, which has recently been estimated to be over $60 billion annually and growing. The projected energy savings resulting from replacing incandescent light bulbs with high-brightness LED's has been estimated to be $35 billion in the USA alone. Other projected benefits include savings of natural resources and reduced emission of green house gases.

A critical issue for GaN LED fabrication is the development of Ohmic contacts to p-type GaN, which optimize both the device power input and the light output. Present technology uses sputtered or e beam evaporated metal films for the electrical contacts. The metal films must be made thin enough to allow for significant light extraction, which compromises power input to the device. In addition, physical vapor deposition (PVD) processes such as sputtering or evaporation result in poor step coverage, sputtering can also generate detrimental surface defects, and evaporation is difficult to scale to high volume production.

We have developed self assembled transparent conductive ZnO based photonic crystal contacts and fabrication technology based on metal organic chemical vapor deposition (MOCVD) of the transparent conductive oxides (TCO's). While we have focused on ZnO, the techniques and principles are amenable to other TCO's, such as indium tin oxide; generally known as ITO, AlCuO and other materials under development. TCO materials such as zinc oxide (ZnO) and indium-tin oxide (ITO) have high transparency at the GaN emission wavelengths, and high electrical conductivity. GaN has a relatively high refractive index which leads to significant light trapping in the device films by total internal reflection—commonly known as light piping. Further, the most commonly used substrate for GaN based devices is Al2O3 followed by SiC, which also limit light efficacy.

Using a TCO, especially ones with certain structural characteristics, for the contact to p-GaN (or n-type surface terminated GaN) allows for both maximum power input to the LED combined with maximum light extraction. This lessons the relative heat loading for a given power input. Replacing the present PVD contact deposition processes with an MOCVD process provides several additional benefits, including improved step coverage, easier scale-up to production volume and reducing the total number of process steps. The MOCVD process disclosed enables contiguous formation of self assembled photonic structures of variable configurations and layering to be produced as desired to optimize the combination of light extraction from the LED, conductivity of the electrical contact and, optionally, incorporation of luminescing components, which can enhance efficiency and/or expand the spectral range of light emitted.

This patent application in particular addresses many of the needs outlined in the U.S. Department of Energy, February 2005 “Solid-State Lighting Program Commercialization Support Pathway” document as summarized in the listing on the following page. The stated goal on pg 9 of the DOE document—“is to reach greater than 160 lumens per watt, which would represent more than an order of magnitude increase in efficiency over incandescent lamps and a two-fold improvement over fluorescent lamps” in the ˜2010 to 2020 timeframe. Our invention(s) speak to that goal.

Gallium nitride is part of a family of materials known as wide bandgap semiconductors. The recent technological and commercial interest in GaN is due to its superior properties. The wide bandgap, high breakdown field and high thermal conductivity of GaN enable high frequency and high power devices, for communications and radar applications. For GaN optoelectronic devices, the wide bandgap enables emission of light in the blue to UV wavelength range, in addition to high speed and high power handling capabilities. These properties enable products such as solar blind UV detectors, blue LED's for indicators, and blue/UV LED's and lasers for optical data storage. The largest market for GaN optoelectronic devices will be for solid state lighting. Fabrication of GaN LED's for solid state lighting (blue and blue/UV with phosphors to yield white light) is the primary focus of SMI's development effort. However, the technology developed will be equally valuable to GaN devices fabrication for many other applications. Other potential light emitting devices that our invention is applicable to include diamond, ZnO itself, other elementary or compound semiconductors, and so forth.

The Next Generation Lighting Initiative (NGLI) Roadmap predicts that LED based solid state lighting will surpass incandescent lighting in total cost effectiveness in the next few years. The cost effectiveness of solid state lighting should surpass fluorescent and high intensity discharge (HID) lamps by 2012. Manufacturing high efficiency high output GaN based LED's economically and in large quantities would not only enable a huge market opportunity, but also tremendous energy savings. Replacing present incandescent lighting with solid state LED's would save up to 50% of electricity usage for lighting in the US, and up to 10% of total electricity usage. Energy savings in the US have been estimated at 525 terawatt-hours per year, or approximately $35 billion.

### SUMMARY OF THE INVENTION

Of the family of wide bandgap semiconductors materials, GaN is the most promising material for blue/UV LED applications. Silicon carbide (SiC) LED's have low efficiency. II-VI materials such as ZnSe have limited lifetimes due to defect generation. Diamond and ZnO based emitters are not yet well developed. The group III nitrides GaN, InN and AlN, are all direct bandgap semiconductors. By suitable alloying, bandgaps from 1.9 eV to 6.2 eV can be engineered. ZnO has an excellent lattice match of to GaN and its alloys. However, it is known that MOCVD can be used to grow columnar structures on materials not well lattice matched to ZnO, as well. For solid state lighting to compete with present technology incandescent, florescent and HID lamps, LED's with white light emissions with color rendering index (CRI) close to 100 are required. There are 3 basic approaches to fabrication of white LED's: 1). Fabricate separate red, green and blue (RGB) LED's on the same chip. 2). Use a blue LED with a yellow phosphor and combine the blue and yellow lights to make white. 3). Use a UV LED with red, green and blue phosphors. Presently, UV LED's with RGB phosphors are nearest to full commercialization. The combined RGB LED approach is considered a future enhancement. It should be pointed out that the TCO contact technology discussed herein is equally applicable to all three approaches, since each will require high brightness GaN based LED's and the present MOCVD process can directly transition the TCO to a phosphor layer itself. Additionally, the TCO approach discussed herein is not limited in applicability to p-type contact layers, nor is it even necessary to be the first or last contact layer and it can be applied to many other material systems.

GaN based LED's are typically fabricated on single crystal sapphire (Al2O3) substrates, due to the lack of suitable GaN substrates. Typically, in production all of the group III-nitride layers are grown by MOCVD, including a low temperature AlN or GaN buffer layer, an n-type Si doped GaN layer, a Mg doped GaN emitter and a Mg doped AlGaN base. The active region is typically a single or multiple quantum well structure. Since the device is fabricated on a dielectric substrate, all electrical contacts must be made to the top surface. Fabricating low resistance Ohmic contacts to n type GaN is relatively straight forward. A high conductivity n-GaN layer is first produced by Si doping, followed by titanium or aluminum based multilayer metallization schemes, such as Ti/Al, Ti/Au, Ti/Al/Ni/Au or Pd/Al.

Fabricating low resistance Ohmic contacts to p-type GaN is more difficult. Part of the issue is the difficulty in producing high conductivity p type GaN. The lack of a highly conductive p-type junction inhibits lateral spreading of current in the top layer of the device. This necessitates a large contact area to the p-GaN layer, which limits light extraction from the top surface. Contacts to p-GaN typically use high work function metals such as Ni, Au, Cr, Pd, Pt and their multilayers. The metals are deposited in thin layers, in order to make semi-transparent contacts. If the metal contacts are too thin, then series resistance increases and contact reliability suffers. If the contact metal layers are too thick, then too much light emission is absorbed or blocked. Present technology for fabrication of GaN LED's uses Ni/Au films, about 30 nm thick, with about 50% transparency, for the contact metal to the p-type junction.

The use of transparent conductive oxides for the contact to p-type GaN is an attractive approach to minimize the power loss and maximize the light extraction from an LED. Indium-tin oxide or ITO films, deposited by e-beam evaporation or sputtering, have previously been investigated for contacts to p GaN. ITO was chosen, in part, in these works because of familiarity with this material from applications such as flat panel displays. In many cases a post deposition anneal is required. In some cases the ITO has been patterned into rod or similar structures to enhance light output, when combined with pore closing electrode technology. Low resistance Ohmic contacts to p-GaN have been reported with improved light output, compared to metal contacts.

ZnO is an ideal contact material because it is transparent throughout the entire visible spectrum and at ultraviolet wavelengths that are often used to pump light-emitting phosphors in white LEDs. ITO can also fulfill this criterion but ZnO has several advantages including better thermal conductivity, a much smaller lattice mismatch to GaN and a superior high temperature stability. In addition, ZnO can be wet and dry etched and doped with aluminum, indium and gallium (among other dopants) to improve conductivity. ZnO also has one other key advantage over ITO for LED manufacturing—a better, more reproducible growth process. ZnO can also be alloyed with other elements such as Mg or Cd to further increase or decrease its bandgap, while maintaining doped conductivity. ITO is deposited by either PVD processes, such as MBE and electron-beam evaporation, or by sputtering. All of these techniques tend to produce poor-quality films on surfaces of varying topography, such as those found on an LED's top surface. This weakness, referred to as poor step coverage, produces poor contact reliability and limits device yield. MBE and electron beam evaporation of ITO are also difficult to scale to large volume production, while sputtering processes actually damage the devices.

The published literature includes a few investigations of ZnO based contacts for p-GaN, including e beam evaporated Ni plus sputtered Al:ZnO [J. O, Song, K. K. Kim, S. J. Park, and T. Y. Seong, “Highly low resistance and transparent Ni/ZnO ohmic contacts to p-type GaN”, Applied Physics Letters, Vol. 83(3), p 479 (2003).], e-beam evaporated In:ZnO [J. H. Lim, D. K. Hwang, H. K. Kim, J. Y. Oh, J. H. Yang, R. Navamathavan and S. J. Park, “Low-resistivity and transparent indium-oxide-doped ZnO ohmic contact to p-type GaN”, Applied Physics Letters, Vol. 85(25), p. 6191 (2004], e-beam evaporated Ni plus Al:ZnO [C. J. Tun, J. K. Sheu, B. J. Pong, M. L. Lee, M. Y. Lee, C. K. Hsieh, C. C. Hu and G. C. Chi, “Applications of transparent Al-doped ZnO contact on GaN-based power LED”, J. Proceedings of the SPIE, Vol. 6121, p. 287 (2006).] and molecular beam epitaxy (MBE) of Ga:ZnO [K. Nakahara, H. Yuji, K. Tamura, S. Akasaka, H. Tampo, S. Niki, A. Tsukazaki, A. Ohtomo and M. Kawasaki, “Two different features of ZnO: transparent ZnO:Ga electrodes for InGaN-LEDs and homoepitaxial ZnO films for UV-LEDs”, Proceedings of the SPIE, Volume 6122, p. 79 (2006).]. For the films deposited by e-beam evaporation or sputtering, a post deposition anneal up to 800 C was done to achieve optimum properties. However, none used self assembly techniques. We have previously investigated planar conductive ZnO films for contact to organic light emitting diodes [Photoemission spectroscopy analysis of ZnO:Ga films for display applications J. Vac. Sci. Technol. A 17(4), July/August 1999 pp 1761-1764] and another group has pursued structured nanocone ZnO as part of the active junction of a ZnO—GaN or ZnO—ZnO based device [U.S. Patent Publication 2007/0158661 A1]

In addition to the materials, the thin film deposition process set forth in this application will also have significant impact on GaN LED fabrication as it saves process steps. By incorporating a phosphor or luminescent layer with the TCO fabrication process, subsequent separate process steps are eliminated or mitigated. Further, stability is enhanced. This is important for the growing Solid State Lighting industry. PVD processes such as MBE, pulsed laser deposition, evaporation and sputtering result in poor step coverage. This is an important consideration since all contacts for GaN based LED's must be made to the top surface of the device, so significant topography will be present. Poor step coverage leads to poor contact reliability, and limits the density of devices that can be produced on each wafer. PVD processes such as MBE and e-beam evaporation are also difficult to scale to large volume production, further limiting the economics of fabrication. Sputtering processes can result in device damage.

On the contrary, CVD and MOCVD processes are readily scaleable to large volume production. MOCVD is compatible with GaN device fabrication, since all of the GaN and related alloy layers are presently deposited by MOCVD. Also, MOCVD is a thermally driven process, so subsequent annealing steps should not be required, further improving the economics of high-brightness LED fabrication. Although deposition of ZnO by MOCVD is an established technology, as is the growth of nanotip or columnar structures; we found no reports in the published literature of contact formation for GaN devices using CVD or MOCVD techniques to form structured thin films for electrical contact; further the concept of combining the contact layer with phosphor layer(s) has also not previously been attempted, either for ZnO or for any other contact material nor for the method or design of self-assembled ZnO (or its alloys or the like) photonic crystals to enhance light extraction from the device by MOCVD. Additionally, the unique capability of MOCVD to address and produce a better contact with minimal surface disruption has also not been investigated as a process. Further, no reports are known of in series phosphor incorporation in single or functionally graded layers using such deposition techniques.

We have developed fabrication technology for GaN LED contacts, based on MOCVD of transparent conductive oxides. We are concentrating on TCO materials based on zinc oxide, due to their desirable properties. However, the general MOCVD process and tool technology results obtained will be equally applicable to more common TCO's such as indium tin oxide (ITO). Most important is our development of the self assembled photonic crystal and multilayer formation technology to maximize current spreading and to mitigate light trapping (maximize light extraction) and the concurrent ability to deposit the TCO films with additional luminescent centers, “phosphors”.

### BRIEF DESCRIPTION OF THE DRAWINGS

For a better understanding of the invention, reference is made to the following drawings which are to be taken in conjunction with the detailed description to follow in which:

FIG. 1 of the drawings illustrates the effect of a transparent conductive film with a self assembled columnar (or semicolumnar) photonic crystal (or wire) grain structure to enhance light output from an LED;

FIG. 2 depicts an exemplary MOCVD deposition reactor chamber that can be used to deposit the transparent conductive film and

FIG. 3 depicts interior of the deposition reactor chamber;

FIGS. 4a-d illustrate various LED designs utilizing a basic epilayer structure with contacts to either side of the device;

FIG. 5 is a photograph showing with actual light output that LEDs with Al doped ZnO contacts as compared to metallic contacts; and

FIG. 6 is SEM micrograph of an MOCVD deposited ZnO film, showing in FIG. 6a a columnar grain structure in FIG. 6b a highly textured structure and in FIG. 6c the extreme of nanowires or whisker structure.

### DESCRIPTION OF THE PREFERRED EMBODIMENTS

### MOCVD Equipment

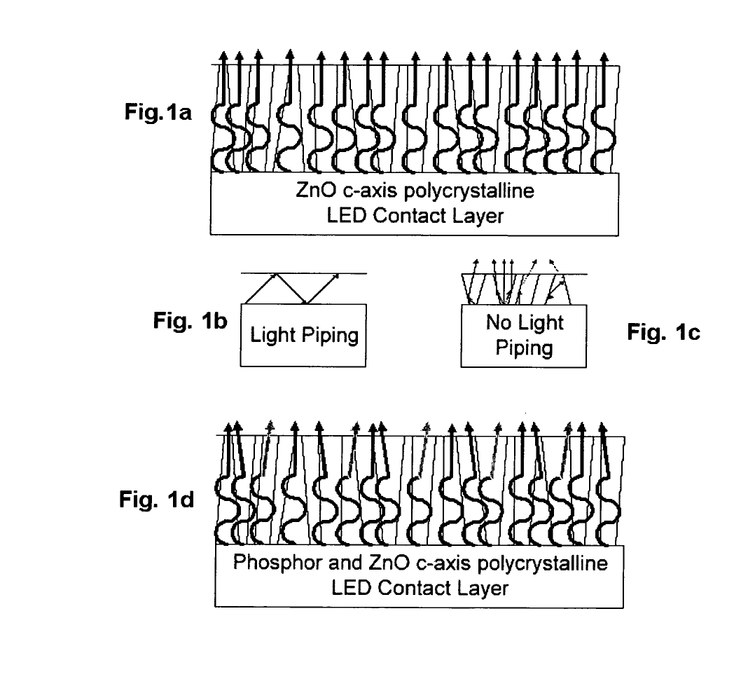

FIG. 1 of the drawings illustrates the effect of a transparent conductive film with a self assembled columnar (or semicolumnar) photonic crystal (or wire) grain structure to enhance light output from an LED. In FIG. 1A the columnar grains of MOCVD deposited ZnO channel and scatter the emitted light in a direction normal to the film surface, and minimize light loss in the direction parallel to the film surface. In FIG. 1B TCO films with equiaxed grains, or amorphous films such as ITO or ZnO films not deposited as described herein, allow lateral propagation or “light piping” of the LED emission in a direction parallel to the film surface which diminishes the usable light output from the device. FIG. 1C shows TCO films with columnar grain structures which inhibit undesirable parallel light piping. FIG. 1D shows that when combined with a thin film phosphor, the columnar grain structure of the transparent conductive oxide film results in utilization of the LED emission for down conversion of the LED light output which results in mono or multi colored light output; including white light.

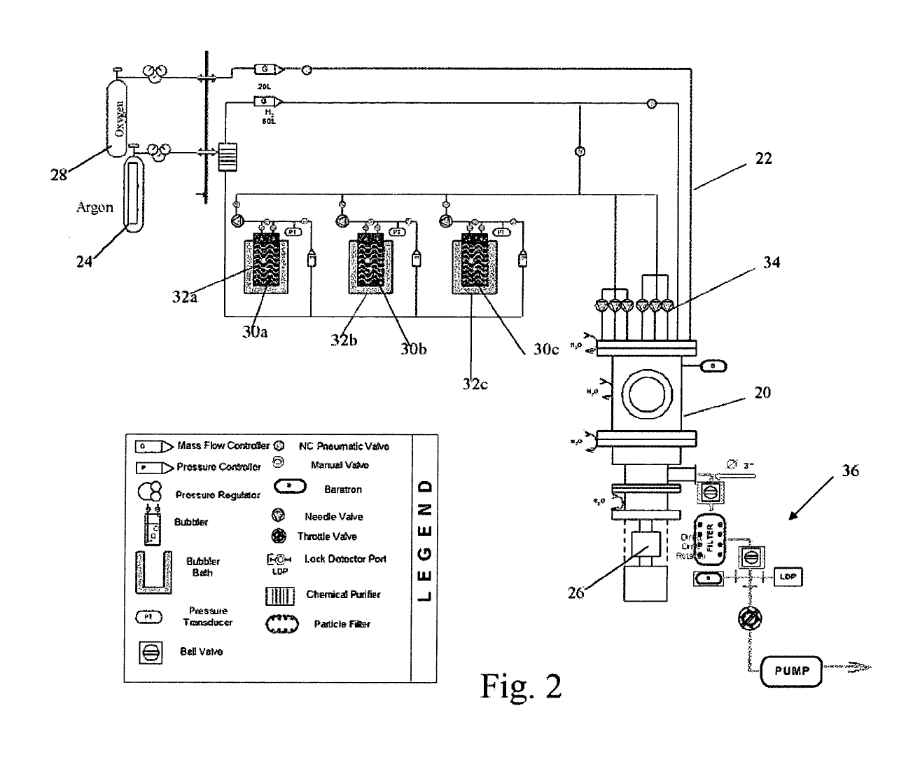

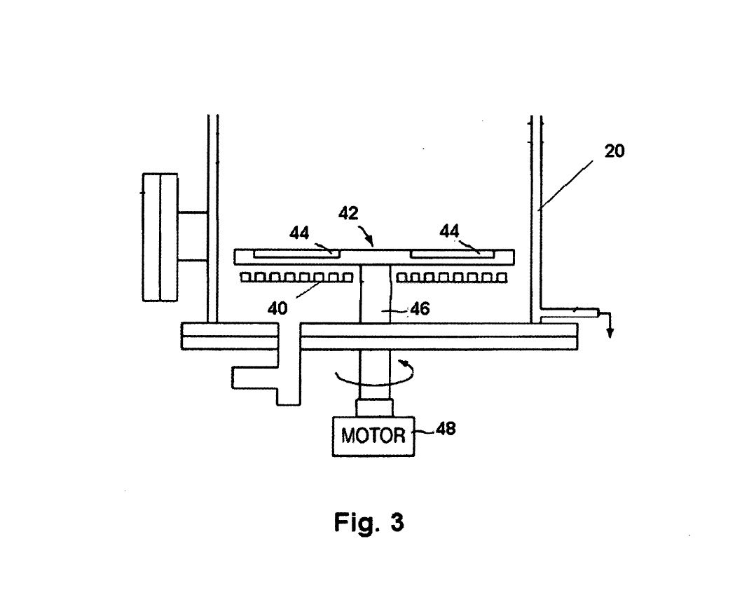

FIG. 2 depicts an exemplary MOCVD deposition chamber that can be used in this work and FIG. 3 depicts interior of the reactor chamber. Gases are fed into a vacuum reactor chamber 20 through a showerhead located inside chamber 20 which contains gas inlets 22 for precursor vapors and a carrier gas 24, which in this case is argon, or other suitable inert gases. Heating of chamber 20 is achieved through resistive heating elements 40 disposed beneath a wafer carrier 42. The chamber pressure is recorded through a baratron. The temperature of chamber 20 is recorded via thermocouples that are positioned in close proximity to wafer carrier 42. The substrates 44 on which the TCO is to be deposited are mounted on wafer carrier 42 that is equipped with a rotation assembly 46 rotated by an external motor 48. During deposition the entire wafer assembly rotates at a predetermined speed as is discussed below.

FIG. 2 also depicts a simplified schematic of the gas panel used for depositing ZnO based films. On the left, an oxygen gas bottle 28 (for the oxidizing gas) and argon gas bottle 24 (for the carrier gas) are shown that tie into the main gas panel. Three bubbler sources 30a, 30b and 30c are depicted in the center of the drawing, one for the zinc precursor diethylzinc (C2H5)2Zn, [abbreviated herein as “DEZn”] one for the aluminum dopant precursor Trimethylaluminum (CH3)3Al [abbreviated herein as “TMAl”] and a spare one that can be used for additional or doping/alloying precursors if so desired. Additional sources and alternative chemistries may be used. Bubbler sources 30a, 30b and 30c are each surrounded by liquid baths 32a, 32b and 32c to maintain the liquid precursors at the desired temperatures The precursor vapors are transported to the showerhead by the Argon carrier gas bubbled therethrough, from where they are fed into the chamber through needle valves 34. The lower right portion of the drawing represents the vacuum pumping manifold 36.

TABLE A
Example of Al-doped ZnO films growth parameters:

| | | |
|---|---|---|
| Substrate temperature: | 450-650° | C. |
| Chamber pressure: | 5-20 | Torr |
| Oxygen flow rate: | 200-500 | sccm |
| Carrier gas (Ar) flow rate: | 4000-7000 | sccm |
| Ar flow rate through DEZn: | 35-70 | sccm @ 17° C. and 350 Torr |
| Ar flow rate through TMA1: | 0-20 | sccm @ 15° C. and 350 Torr |
| Sample rotation speed: | 750 | rpm |
| Growth rate: | 100-230 | A/min |

The above parameters results in a ZnO:Al conductive transparent material which is n-type due to the Al dopant. Other suitable dopants include Ga, In, N, P and/or Sb.

We have demonstrated the benefit of ZnO contacts by depositing them on GaN epiwafers. These aluminum-doped ZnO contacts, which have a thickness uniformity of a few percent, were deposited with a growth rate of 10-20 nm/min and form a good ohmic contact with a resistance of less than 10−3 Ω/cm. The performance of these ZnO-contacted LEDs was compared with two different control devices made from a conventional NiAu thin film and ITO. At drive currents from 10 to 80 mA, the LEDs with a ZnO contact delivered 70 and 30% more light than the devices with metal and ITO contacts, respectively The ZnO-based LEDs also produced a five-fold or more gain in lifetime during a conventional burn-out test. Table B below shows test results:

TABLE B
Example Test Results for SMI AZO?? on GaN base LED Sample

| | | |
|---|---|---|
| | GZ2395B | GZ2395B |
| Wafer ID | (without ZnO) | (with ZnO) |

| | | | | |
|---|---|---|---|---|
| Power @ 20 mA | 0.5 | mW | 0.6246 | mW |
| Power @ 100 mA | 1.817 | mW | 2.4 | mW |
| Wavelength @ 20 mA | 464 | nm | 464.74 | nm |
| Wavelength @ 100 mA | 463 | nm | 462.92 | nm |
| Vf @ 20 mA | 4.73 | V | 3.4 | V |
| Vf @ 100 mA | 7.21 | V | 5.68 | V |

The Al-doped films exhibited resistivities in the 1×10−3 ohm-cm range and a transmissivity of greater than 80%.

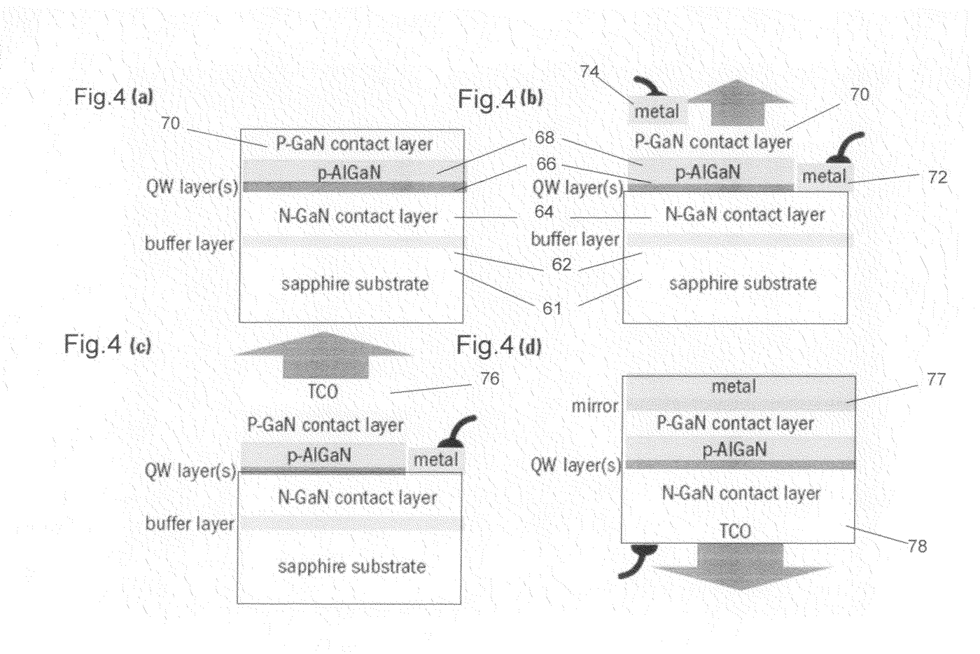

FIGS. 4a-d illustrate various LED designs utilizing a basic epilayer structure 60 shown in FIG. 4a which includes a substrate 61, a buffer layer 62 an N—GaN contact layer 64, quantum well layer(s) 66, a p-AlGaN cladding layer 68 (i.e. a combination index and light guiding layer) and a P—GaN contact layer 70. As shown in FIG. 4b in order to make electrical contact with structure 61 layers 70, 68 and 66, are removed, usually by etching, and a metallic contact 72 is deposited on N—GaN contact layer 64 with a metallic contact 74 deposited on N—GaN contact layer 64. However metallic contacts 72, 74 block the light emission and reduce the effective emission area. A transparent TCO layer 76 can replace metallic contact 76 deposited on N—GaN contact layer 64 and thus increase light output as shown in FIG. 4c. A “flip-chip” structure shown in FIG. 4(d) which includes a mirror 77 may also incorporate a transparent TCO layer 78 FIG. 2. (left) MOCVD-grown ZnO films have a transparency of 85-90% and can be easily etched and thus form a very effective TCO layer.

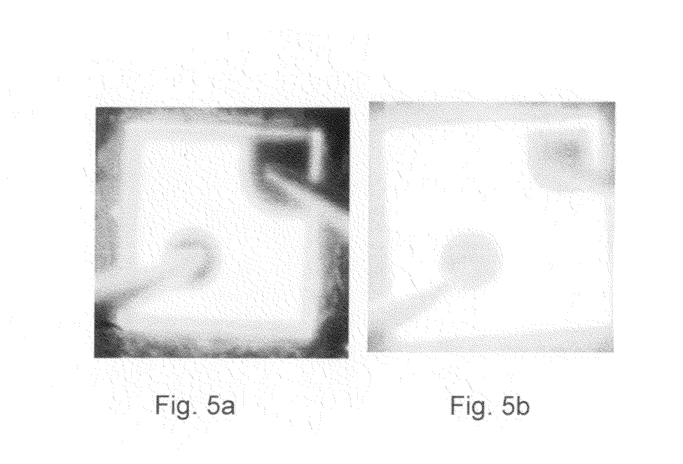

FIG. 5 is a photograph showing with actual light output that LEDs with Al doped ZnO contacts had higher light extraction efficiency than equivalents with metallic and ITO contacts. At 40 mA, the Ni/Au-contacted GaN LED FIG. 5(a) produced 9 mcd (milli candela) and the ZnO contacted equivalent FIG. 5 (b) produced 355 mcd. The ITO variant, which is not shown, produced 27 mcd. It is clearly seen that the Al doped ZnO contacts provide visibly higher light output from the GaN LED.

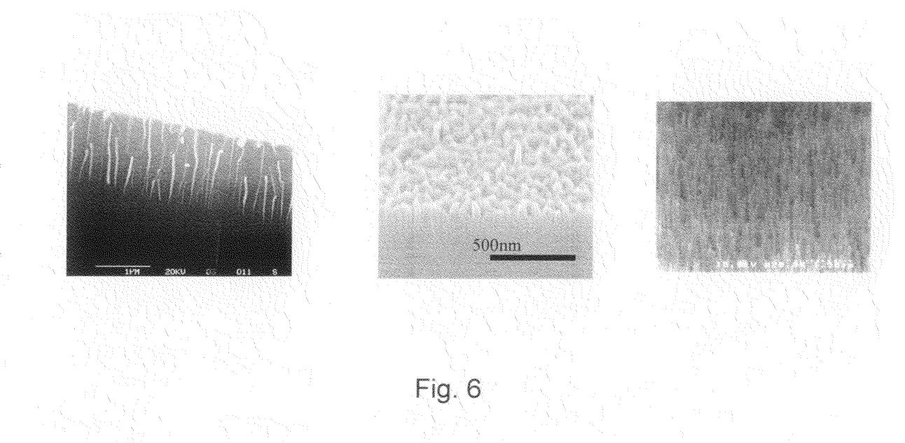

FIG. 6 is SEM micrograph of an MOCVD deposited ZnO films, showing in FIG. 6a a columnar grain structure in FIG. 6b a highly textured structure and in FIG. 6c the extreme of nanowires or whisker structure. The film structure can also be grown so that it is porous. It has been found that optimum results (i.e highest light output) are found in a “semi-columnar” grain structure with a smooth lower portion (in contact with the LED) and a columnar grain structure at the top with a “rough” upper surface (such as shown in FIG. 6b. The “wire” structure of FIG. 6c has been found to less effective due to the spaces between the individual wires.

The above described equipment and methodology may also be used for the MOCVD of phosphor materials, which can be directly incorporated during the TCO deposition step. The phosphor layer can be rare earth doped ZnO (itself is a blue-white phosphor) or doped ZnSiO (for example ZnSiO:Mn, a green phosphor, as grown by MOCVD or the ZnO can be used as a phosphor itself, where the non-band-edge photoluminescence can be controlled by the process parameters and can be varied through the layer. We have previously demonstrated that ZnSiO:Mn can be grown by MOCVD. This provides another significant economic advantage in production of white LED's for solid state lighting. The deposition of passivation layers directly on ZnO films, such as Al2O3 film on ZnO may also be done. Further, the ability to deposit these films through a physical mask (i.e. “patterned”) may also be a part of the deposition process. Additionally, the surface can also be terminated with an entirely different material or even a thinner than usual metal layer and then be contacted with the TCO described herein.

Routes to higher outputs and efficient manufacturing include the use of two coupled reactors to allow films formed in one reactor not to interfere with films formed in a second reactor without subjecting the films to atmospheric exposure. Alternatively the second (or even a third) reactor can be used for oxide compatible passivation layers such as Al2O3. This additional aspect allows us to also integrate p-type ZnO layers into the contact layers as well as n-type layers with minimal process memory effects. This allows the phosphor doped layers in ZnO LED applications to control, augment and expand the spectral range and intensity achievable with ZnO alone. Further, the ability to have p and n type films intermixed with enhanced luminescence layer films furthers device making capabilities. The present MOCVD technology enables several significant advantages to the LED manufacturers, such as reduced processing steps, improved contact reliability, increased efficiency, and more devices per wafer.

In summary the composition and process steps of the deposited TCO may be modified in a number of ways to provide complete control of the properties of the light emitting device, for example:

a. GaN or ZnO LED with contacts fabricated using MOCVD deposited transparent conductive zinc oxide, in which the zinc oxide is doped with elements such as Al, Ga, In, N, P, As, or Sb for enhanced conductivity.

b. GaN or ZnO LED with contacts fabricated using MOCVD deposited transparent conductive zinc oxide, in which the zinc oxide is doped with elements such as Mg or Cd to modify the bandgap.

c. GaN or ZnO LED with contacts fabricated using MOCVD deposited transparent conductive zinc oxide, in which the zinc oxide is doped with elements such as Be, Mg or Cd to modify the index of refraction.

d. GaN or ZnO LED with contacts fabricated using MOCVD deposited transparent conductive oxide—with or without phosphor layer, followed by thermal annealing to improve crystallinity of transparent conductive oxide.

e. GaN or ZnO LED with contacts fabricated using MOCVD deposited transparent conductive oxide—with or without phosphor layer, followed by laser annealing to improve crystallinity of transparent conductive oxide.

f. A TCO contact layer with an integrated phosphor layer and metal grid work to increase the current capacity of the TCO.

g. The use of an interconnected multiple reactor deposition system to enhance the manufacturability of the TCO contact and or phosphor and or passivation layers without exposure to detrimental atmospheric effects and without layer to layer cross contamination of the doping species (memory effects) of prior layers

The above described MOCVD deposition technique provides several advantages for high brightness LED fabrication, including:

1. The capability to directly incorporate phosphors with the transparent contact, in a single or common environment sequential process step using MOCVD.
2. The capability to directly incorporate passivation layers for the transparent contact, in a single or common environment sequential process step using MOCVD.
3. The capability to control the microstructure of the transparent contact materials, for optimum light extraction using MOCVD.
4. The ability to implement the above capabilities into a complete solution to growth of ZnO LEDs and ZnO LEDs with integrated phosphor layers by using MOCVD and or other deposition tools on one platform.
5. The capability to functionally change the bandgap and index of the contact or phosphor layer.
6. The ability to functionally vary the structural nature of the films from amorphous to crystalline to planar to columnar to wires by using MOCVD and or other deposition tools on one platform.

These results illustrate the potential of ZnO contacts but we believe many further improvements in LED performance are possible through engineering the bandgap of ZnO alloys, the incorporation of photonic crystal structures and direct deposition of phosphor structures. CdZnO and MgZnO alloys can also be grown by MOCVD and would allow tuning of the contact's bandgap and optical properties to optimize a particular LED design. Rare-earth elements, such as thulium, manganese, erbium, terbium, and europium, could also be added during ZnO growth to produce luminescent contacts using either a single or dual deposition system. Growing and passivating a light emitter without breaking vacuum is also an option and a simple structure containing a green phosphor, ZnSiO:Mn, which produces cathodoluminescence, electroluminescence and photoluminescence can be readily fabricated. Our results demonstrate that ZnO contacts can improve GaN LED performance.

The present invention has been described with respect to exemplary embodiments. However, as those skilled in the art will recognize, modifications and variations in the specific details which have been described and illustrated may be resorted to without departing from the spirit and scope of the invention as defined in the claims to follow.

What is claimed is:

1. A transparent conductive oxide contact layer to enhance spectral output of a light emitting device comprising a transparent conductive oxide deposited on the light emitting device so as to have a columnar structure.

2. The transparent conductive oxide contact layer as claimed in claim 1 wherein the oxide comprises at least one of ZnO, AlCuO and ITO.

3. The transparent conductive oxide contact layer as claimed in claim 1 wherein the oxide is doped with a conductive element selected from the group of: Al, Ga, In, N, P and Sb.

4. The transparent conductive oxide contact layer as claimed in claim 1 wherein the oxide layer includes light emitting phosphors deposited therein.

5. The transparent conductive oxide contact layer as claimed in claim 1 wherein the layer is deposited by Chemical vapor deposition.

6. The transparent conductive oxide contact layer as claimed in claim 1 wherein the light emitting device comprises a gallium nitride (GaN) light emitting diode.

7. The transparent conductive oxide contact layer as claimed in claim 1 wherein the oxide layer includes bandgap modifying layers deposited therein.

8. In a light emitting device having multiple layers the improvement comprising a transparent conductive contact layer deposited directly on said light emitting device by chemical vapor deposition the transparent conductive contact layer have a columnar structure so as to direct the emitted light in a direction normal to the surface of the device.

9. The light emitting device as claimed in claim 8 wherein the transparent conductive contact layer comprises ZnO doped with a conductive element.

10. The light emitting device as claimed in claim 9 wherein the conductive element comprises at least one of: Al, Ga, In, N, P, As, and Sb.

11. The light emitting device as claimed in claim 8 further including a light emitting phosphor deposited within the transparent conductive contact layer during the chemical vapor deposition process.

12. The light emitting device as claimed in claim 8 further including a passivation layer deposited on the transparent conductive contact layer during the chemical vapor deposition process.

13. The light emitting device as claimed in claim 8 wherein the light emitting device comprises a gallium nitride (GaN) light emitting diode.

14. A method for deposition of a transparent conductive oxide contact layer comprising the steps of:
a) providing a light emitting device;
b) placing said a light emitting device in a CVD reaction chamber;
c) depositing a transparent conductive oxide contact layer utilizing a carrier gas bubbled through liquid precursors of the components of the transparent conductive and an oxidizing gas; and
d) controlling the parameters of the deposition process so that the transparent conductive oxide is formed with at least a partially columnar structure.

15. The method for deposition as claimed in claim 14 wherein the transparent conductive oxide comprises ZnO doped with a conductive element.

16. The method for deposition as claimed in claim 15 wherein the conductive element is selected from the group of: Al, Ga, In, N, P and Sb.

17. The method for deposition as claimed in claim 14 further including the step of depositing light emitting phosphors within the transparent conductive oxide contact layer.

18. The method for deposition as claimed in claim 14 wherein the oxide comprises at least one of ZnO, AlCuO and ITO.

19. The method for deposition as claimed in claim 14 further including the step of annealing the transparent conductive oxide to modify its properties.
